(19) United States
(12) Patent Application Publication
(10) Pub. No.: US 2025/0054893 A1
(43) Pub. Date: Feb. 13, 2025

(54) Component Carrier and Method of Manufacturing the Same

(71) Applicant: AT&S Austria Technologie & Systemtechnik AG, Leoben (AT)

(72) Inventors: Artan BAFTIRI, Chongqing (CN); Minwoo LEE, Chongqing (CN); Patrick LENHARDT, Spielberg (AT)

(21) Appl. No.: 18/693,609

(22) PCT Filed: Apr. 26, 2023
(86) PCT No.: PCT/EP2023/061034

§ 371 Date: Mar. 20, 2024

(30) Foreign Application Priority Data
May 5, 2022 (CN) 202210481885.6

(51) Int. Cl. H01L 23/00; H01L 23/31; H01L 25/00; H01L 25/065

(52) U.S. Cl. CPC H01L 24/20; H01L 23/3107; H01L 24/19; H01L 25/0652; H01L 25/50; H01L 24/32; H01L 24/73; H01L 2224/19; H01L 2224/2101; H01L 2224/32145; H01L 2224/73267; H01L 2225/06568

(57) ABSTRACT

A component carrier including a stack having at least one electrically conductive layer structure and at least one electrically insulating layer structure; a first component embedded in the stack; a second component mounted on the first component and in a cavity which is delimited by an interface surface of the stack; and an electrically insulating filling which at least partially fills the cavity and extends up to the interface surface and thereby forms an interface with at least one of the at least one electrically insulating layer structure.

### CROSS-REFERENCE TO RELATED APPLICATIONS

This application is a national stage application, filed under 35 U.S.C. § 371, of International Patent Application No. PCT/EP2023/061034, filed on Apr. 26, 2023, claiming priority of the Chinese Patent Application No. CN 202210481885.6, filed on May 5, 2022, the disclosures of which are hereby incorporated by reference herein in their entirety.

### TECHNICAL FIELD

The disclosure relates to a component carrier and to a method of manufacturing the same.

### TECHNOLOGICAL BACKGROUND

A conventional component carrier comprises a stack having at least one electrically conductive layer structure and at least one electrically insulating layer structure, and a component embedded in the stack. Some conventional component carriers require stacking of wire bonded components on top of a core. This allows a modularization and splitting of different functionalities in different modules. However, the alignment of the top die is not representative because the connected components are attached to each other before embedding the same into the core. Furthermore, the center core cavity is relatively large, the volume to be filled is large, and there is a higher risk of shift of the components. Besides, the risk of warpage is increased.

### SUMMARY

There may be a need to provide a thin component carrier and a method of manufacturing the same, by which shift and warpage can be reduced.

According to an exemplary embodiment of the disclosure, a component carrier comprises a stack comprising at least one electrically conductive layer structure and at least one electrically insulating layer structure; a first component embedded in the stack; a second component mounted on the first component and in a cavity which is delimited by an interface surface of the stack; and an electrically insulating filling which at least partially fills the cavity and extends up to the interface surface and thereby forms an interface with at least one of the at least one electrically insulating layer structure.

According to another exemplary embodiment of the disclosure, a method of manufacturing a component carrier comprises providing a stack comprising at least one electrically conductive layer structure and at least one electrically insulating layer structure; embedding a first component in the stack; mounting a second component on the first component and in a cavity which is delimited by an interface surface of the stack; and at least partially filling the cavity with an electrically insulating filling which extends up to the interface surface and thereby forms an interface with at least one of the at least one electrically insulating layer structure.

### OVERVIEW OF EMBODIMENTS

In the following, further exemplary embodiments of the present disclosure will be explained.

In an embodiment, the component carrier further comprises a third component mounted on the second component and in a further cavity which is delimited by a further interface surface of the stack, and a further electrically insulating filling which at least partially fills the further cavity and extends up to the further interface surface and thereby forms an interface with at least one of the at least one electrically insulating layer structure.

In an embodiment, the component carrier further comprises a third component mounted side-by-side with the second component on the first component.

In an embodiment, an entire bottom of the cavity is defined by an upper main surface of the first component.

In an embodiment, the component carrier further comprises a stop layer on an upper main surface of the first component and configured for stopping a cavity formation process. Preferably, the stop layer is a copper layer and/or a releasable layer on an upper main surface of the first component and configured for stopping a cavity formation process.

In an embodiment, the electrically insulating filling and the at least one electrically insulating layer structure are made of different materials.

In an embodiment, the electrically insulating filling and the at least one electrically insulating layer structure are made of the same materials.

In an embodiment, the component carrier further comprises an electrically conductive, a non-conductive or insulating adhesive between the first component and the second component.

In an embodiment, the first component and the second component are electrically coupled with each other directly via their mutually facing main surfaces. by a metallic structure, preferably by a solder structure or a sinter structure. Alternatively, any bonding structure such as a hybrid bonding structure, a fusion bonding structure, or a copper bonding structure can be used.

In an embodiment, at least one of the first component and the second component comprises at least one through via passing through the at least one of the first component and the second component. This configuration shortens the signal path of the components and the component carrier to reduce the loss and energy consumption.

In an embodiment, the first component and the second component are electrically coupled with each other indirectly via at least one of the at least one electrically conductive layer structure.

In an embodiment, the at least one of the at least one electrically insulating layer structure is thermally conductive, in particular comprises a thermal prepreg.

In an embodiment, the at least one of the first component and the second component is an active or passive electronic component, in particular a processor, a power chip, a communication chip, a perception chip or a memory chip.

In an embodiment, the at least one of the first component and the second component is a thermally conductive block, in particular a copper block or a ceramic block.

In an embodiment, a pitch which is a center to center distance of pads of the second component is smaller than a pitch of the first component.

In an embodiment, the first component has a larger main surface than the second component.

In an embodiment, the component carrier comprises at least one of the following features: the component carrier comprises at least one other component being surface mounted on and/or embedded in the component carrier, wherein the at least one other component is in particular selected from a group consisting of an electronic component, an electrically non-conductive and/or electrically conductive inlay, a heat transfer unit, a light guiding element, an optical element, a bridge, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip; wherein at least one of the electrically conductive layer structures of the component carrier comprises at least one of the group consisting of copper, aluminum, nickel, silver, gold, palladium, and tungsten, any of the mentioned materials being optionally coated with supra-conductive material such as graphene; wherein the electrically insulating layer structure comprises at least one of the group consisting of resin, in particular reinforced or non-reinforced resin, for instance epoxy resin or bismaleimide-triazine resin, FR-4, FR-5, cyanate ester resin, polyphenylene derivate, glass, prepreg material, polyimide, polyamide, liquid crystal polymer, epoxy-based build-up film, polytetrafluoroethylene, a ceramic, and a metal oxide; wherein the component carrier is shaped as a plate; wherein the component carrier is configured as one of the group consisting of a printed circuit board, a substrate, and an interposer; wherein the component carrier is configured as a laminate-type component carrier.

In an embodiment, the cavity is narrowed toward the first component. In an embodiment, an area defined on a bottom of the cavity is greater than the area defined by the second component of a percentage range from 1 to 20%. In an embodiment, the cavity extends along a direction from the second component to the third component with a width defined on the bottom of the cavity that is greater than the width of the respective second and third components of a percentage range from 1 to 20%. In an embodiment, an area defined by a bottom of the further cavity is greater than an area defined by the third component of a percentage range from 1 to 20%. In an embodiment, the cavity extends up to a next layer structure next to a component (main) area where the cavity merges. In an embodiment, the cavity extends up to a next conductive layer structure. In an embodiment, a height of the cavity along a stack thickness is greater than a height of the second component mounted in the cavity. By these features, a reliable positioning and/or centering of the second and/or third component and a consequent homogeneous and/or balanced heat distribution can be achieved, wherein the upper component can properly be positioned and/or centered on the respective bottom component. This advantage is also achieved in case of side-by side upper components due to their precise positioning.

In an embodiment, pads of the first component, the second component, or the third component are directly exposed at an external main surface of the stack. In an embodiment, the pads of the first component, the second component, or the third component are connected to a sputtered layer on the external main surface of the stack. In an embodiment, the first, second, and/or third component comprises at least one connecting pad on a respective main surface facing an external surface of the stack, wherein the first, second, and/or third component comprises a lateral surface and the electrically insulating layer structure is in contact with the lateral surface and the at least one pad of the first, second and/or third component. In an embodiment, the electrically insulating filling material is in contact with the lateral surface and the pad of the first component. In an embodiment, the electrically insulating filling and/or the further electrically insulating filling is in contact with the lateral surface and the pad of the respective second and/or third component. These features in conjunction with the features concerning the cavity, the interface surface and the insulating filling allow an enhancement of the carrier mechanical properties due to a constant CTE and a constant elastic module around the components, and warpage can be suppressed.

In an embodiment, the stack comprises at least one via having two sub-portions opposed with respect to a stack thickness, each sub-portion being narrowed toward an internal portion of the stack and both sub-portions are connected to each other by a narrowed section. These features allow a better copper distribution along the stack thickness, that in conjunction with the cavity, components positioning and the eventual insulating structure around the components and the respective pads allow a more balanced structure in the compact design of the component carrier. The opposed slanted sub-portion can be realized by flipping the stack in the manufacturing process.

In an embodiment, the method further comprises a step of using the same alignment marks for embedding the first component and for mounting the second component.

Advantageously, a surface finish area can be reduced so that also the costs are reduced. The component carrier can have a reduced height (in z-direction), and the component carrier can exhibit better electrical performances.

The attachment of the second component is done after having inserted the first component into the cavity. Thereby, the second component such as a die can be aligned on a top side pattern of the component carrier, which results in a better registration.

An encapsulation volume in the cavity can be reduced, and the second component can be attached on a die top surface of the first component, which minimizes a shift risk. Besides, a warpage risk and a scale value can also be reduced.

In an embodiment of the method, pads of the first component, the second component, or the third component are directly exposed at an external main surface of the stack; and the pads of the first component, the second component, or the third component are connected to a sputtered layer on the external main surface of the stack. Advantageously, it helps to shorten the signal path between the component and component carrier, which should have a good signal integrity, and the layer count of the component carrier, which can reduce the manufacturing costs and increase the yield.

In an embodiment, a top side of the stack and the pads of the first component, the second component or the third component are ground; thereafter, the electrically conductive structures are sputtered on a ground surface of the stack and the pads of the first component, the second component or the third component; thereafter, the sputtered electrically conductive structures are patterned.

In an embodiment, the cavity is formed by use of a stop layer or a releasable layer on an upper main surface of the first component, wherein the stop layer is configured for enhancing a cavity formation process.

Compared with a prior art EMIB (Embedded-Multi-Die-Interconnect-Bridge), the present disclosure uses for example a copper layer on the first component, and the component carrier according to the present disclosure enables an easy symmetric build-up in center core configuration.

Because substantially no additional material is present in between the stacked first and second components, the height in the z-direction can further be reduced, and wire bonding processes can be avoided due to no additional material for stacking dies, wherein the signal integrity and package reliability are improved.

A high accuracy for embedded component and alignments to respective layers (bottom component to back side alignment, and top component to top side alignment) can be maintained.

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming through-holes through the laminate, for instance by laser drilling or mechanical drilling, and by filling them with electrically conductive material (in particular copper), thereby forming vias as through-hole connections. Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Size Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) or a photoimageable or dry-etchable organic material like epoxy-based build-up material (such as epoxy-based build-up film) or polymer compounds like polyimide, polybenzoxazole, or benzocyclobutene-functionalized polymers.

In an embodiment, the at least one electrically insulating layer structure comprises at least one of the group consisting of resin (such as reinforced or non-reinforced resins, for instance epoxy resin or bismaleimide-triazine resin), cyanate ester resin, polyphenylene derivate, glass (in particular glass fibers, multi-layer glass, glass-like materials), prepreg material (such as FR-4 or FR-5), polyimide, polyamide, liquid crystal polymer (LCP), epoxy-based build-up film, polytetrafluoroethylene (PTFE, Teflon®), a ceramic, and a metal oxide. Teflon is a registered mark of the Chemours Company FC, LLC of Wilmington, Delaware, U.S.A. Reinforcing structures such as webs, fibers or spheres, for example made of glass (multilayer glass) may be used as well. Although prepreg particularly FR4 are usually preferred for rigid PCBs, other materials in particular epoxy-based build-up film or photoimageable dielectric material may be used as well. For high-frequency applications, high-frequency materials such as polytetrafluoroethylene, liquid crystal polymer and/or cyanate ester resins, low temperature cofired ceramics (LTCC) or other low, very low or ultra-low DK materials may be implemented in the component carrier as electrically insulating layer structure.

In an embodiment, the at least one electrically conductive layer structure comprises at least one of the group consisting of copper, aluminum, nickel, silver, gold, palladium, titanium and tungsten. Although copper is usually preferred, other materials or coated versions thereof are possible as well, in particular coated with supra-conductive material such as graphene.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an optical element (for instance a lens), an electronic component, or combinations thereof. For example, the component can be an active electronic component, a passive electronic component, an electronic chip, a storage device (for instance a DRAM or another data memory), a filter, an integrated circuit, a signal processing component, a power management component, an optoelectronic interface element, a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium phosphide (InP), indium gallium arsenide (InGaAs) and/or any other suitable inorganic compound), a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be a substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such as solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), gold (in particular Hard Gold), chemical tin, nickel-gold, nickel-palladium, ENIPIG (Electroless Nickel Immersion Palladium Immersion Gold), etc.

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1 illustrates a cross-sectional view of a component carrier according to an exemplary embodiment of the disclosure.

FIG. 2 illustrates a method of manufacturing a component carrier according to the embodiment of FIG. 1.

FIG. 3 illustrates the method of manufacturing the component carrier according to the embodiment of FIG. 1.

FIG. 4 illustrates a method of manufacturing a component carrier according to an exemplary embodiment of the disclosure.

FIG. 5 illustrates a method of manufacturing a component carrier according to an exemplary embodiment of the disclosure.

FIG. 6 illustrates a cross-sectional view of a component carrier according to an exemplary embodiment of the disclosure.

FIG. 7 illustrates a method of manufacturing a component carrier according to an exemplary embodiment of the disclosure.

FIG. 8 illustrates a cross-sectional view of a component carrier according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

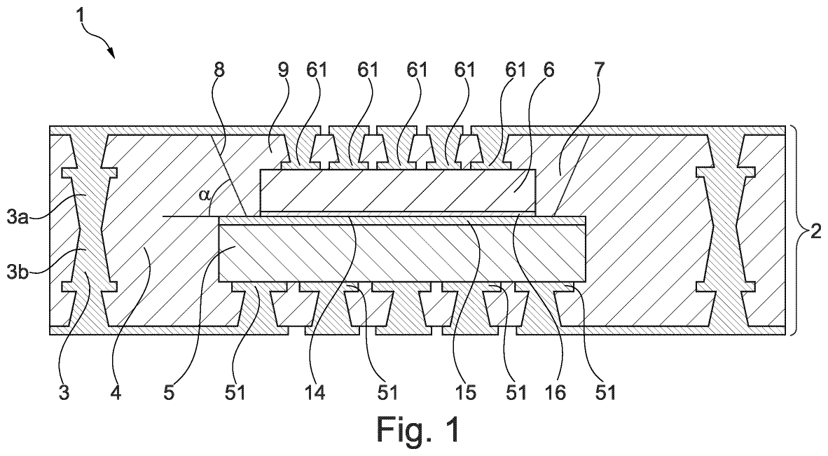

FIG. 1 illustrates a cross-sectional view of a component carrier 1 according to an exemplary embodiment of the disclosure. The component carrier 1 of this embodiment is configured as one of the group consisting of a printed circuit board, a substrate, and an interposer.

The component carrier 1 comprises a stack 2 comprising at least one electrically conductive layer structure 3 and at least one electrically insulating layer structure 4. The at least one electrically conductive layer structure 3 of the component carrier 1 comprises at least one of the group consisting of copper, aluminum, nickel, silver, gold, palladium, titanium and tungsten, any of the mentioned materials being optionally coated with supra-conductive material such as graphene. The at least one electrically insulating layer structure 4 comprises at least one of the group consisting of resin, in particular reinforced or non-reinforced resin, for instance epoxy resin or bismaleimide-triazine resin, FR-4, FR-5, cyanate ester resin, polyphenylene derivate, glass, prepreg material, polyimide, polyamide, liquid crystal polymer, epoxy-based build-up film, polytetrafluoroethylene, a ceramic, and a metal oxide. The at least one electrically insulating layer structure 4 can be thermally conductive, in particular comprises a thermal prepreg.

The component carrier 1 comprises a first component 5 and a second component 6. The first and second components 5, 6 are particularly selected from a group consisting of an electronic component, an electrically non-conductive and/or electrically conductive inlay, a heat transfer unit, a light guiding element, an optical element, a bridge, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip. Preferably, the first component 5 and the second component 6 are electronic components, in particular of a group consisting of a processor, a power chip, a memory chip, a communication chip, or a perception chip. Alternatively, at least one of the first component 5 and the second component 6 can be a thermally conductive block, in particular a copper block or a ceramic block.

A pitch of the first component 5, which is a center to center distance of pads 51 of the first component 5, is larger than a second pitch of the second component 6, which is a center to center distance of pads 61 of the second component 6. The first component 5 can have a larger main surface than the second component 6 so that the first and second components 5, 6 form a stepped structure.

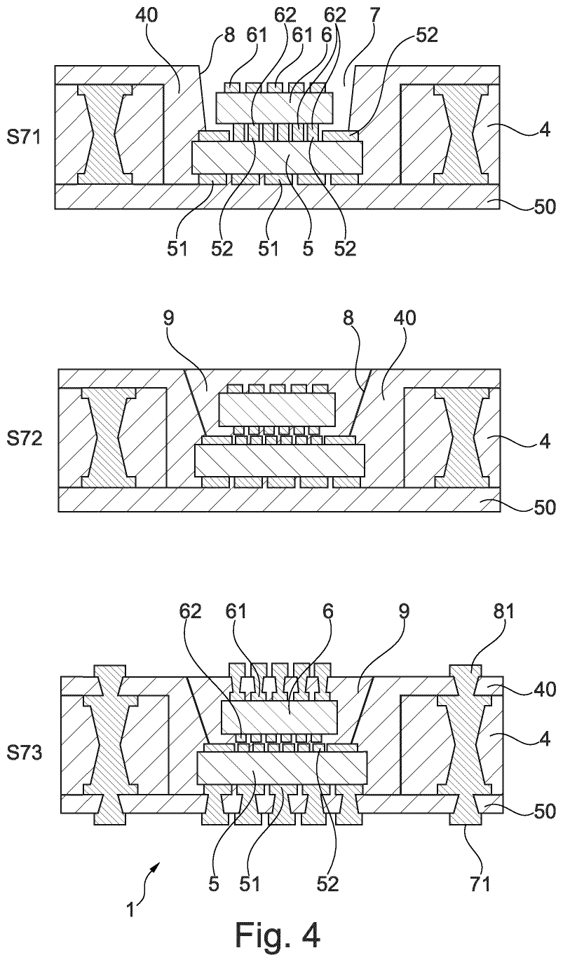

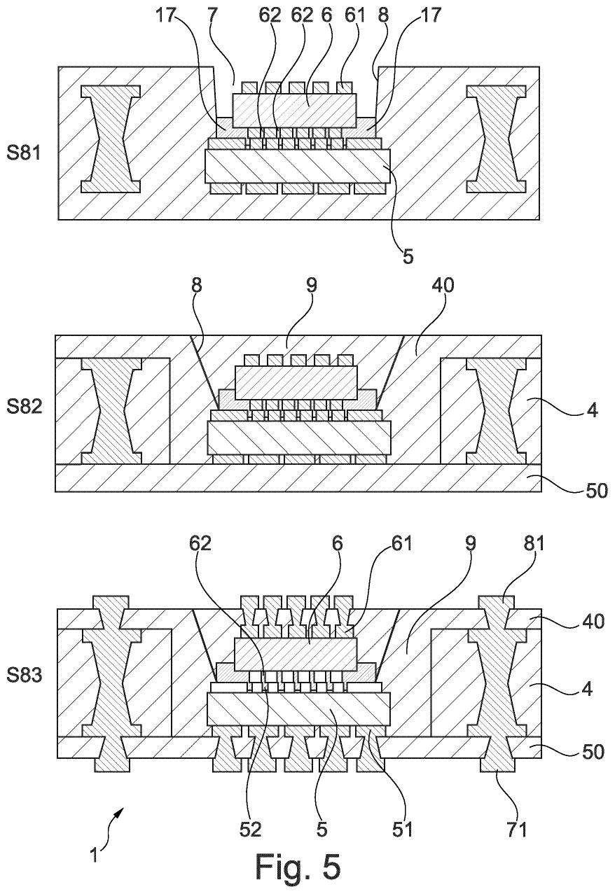

The first component 5 is embedded in the stack 2, and the second component 6 is mounted on the first component 5. In particular, an adhesive 16, more particularly an electrically conductive adhesive, is provided between the first component 5 and the second component 6. The adhesive 16 can have an electrically conductive, a non-conductive or an insulating property. Alternatively, a bonding structure can be provided between the first component 5 and the second component 6. The first component 5 and the second component 6 are electrically coupled with each other indirectly via at least one of the at least one electrically conductive layer structure 3. Alternatively, the first component 5 and the second component 6 can be electrically coupled with each other directly via their mutually facing main surfaces (FIG. 4 and FIG. 5).

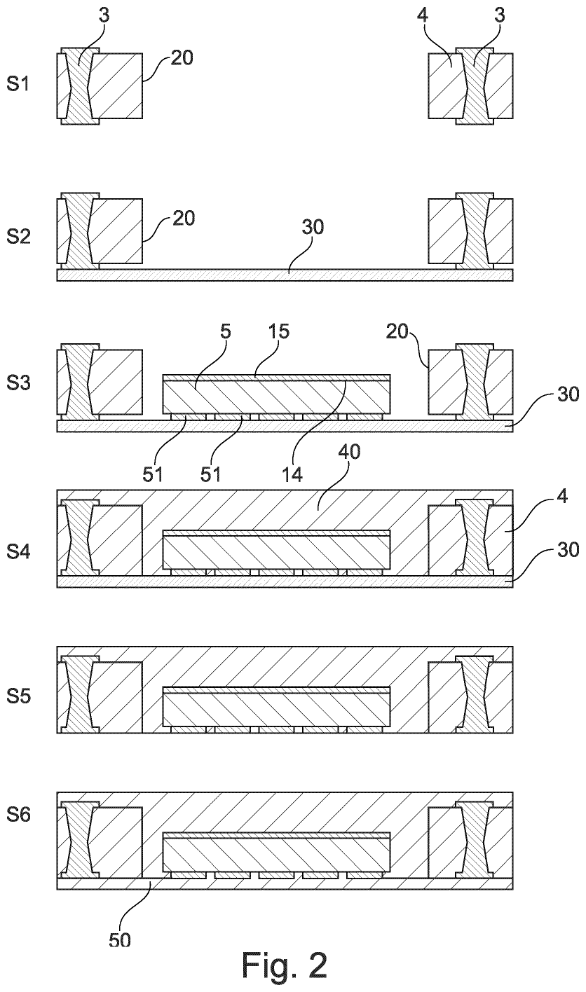

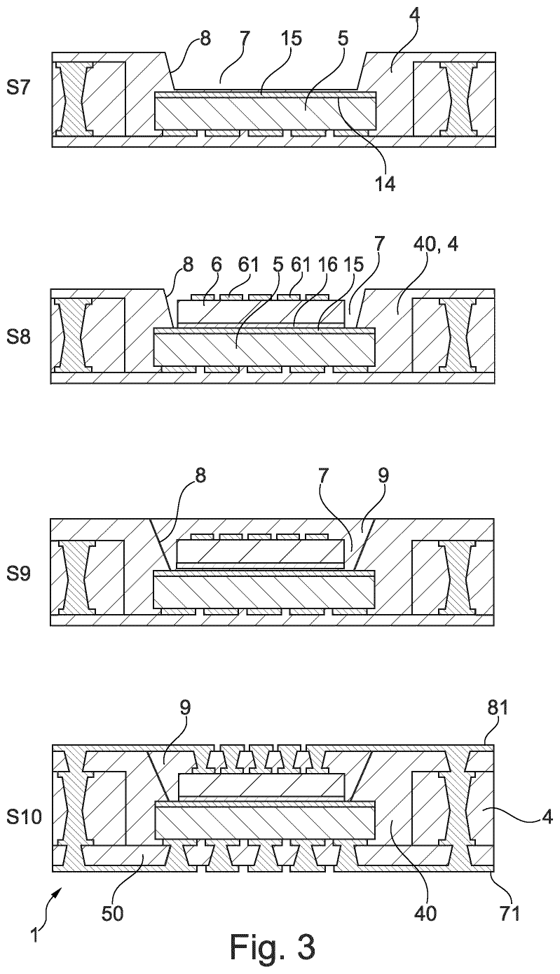

The second component 6 is arranged in a cavity 7 which is radially delimited by an interface surface 8 of the stack 2. An entire bottom of the cavity 7 is defined by an upper main surface 14 of the first component 5. An angle α between the upper main surface 14 of the first component 5 and the interface surface 8 is preferably between 30° and 90°, more preferred larger than 45° and smaller than 88°. By such values of the angle α, the cavity 7 can be made by laser processing. The interface surface 8 of the stack 2 is described in more detail in FIG. 2 and FIG. 3.

The component carrier 1 comprises an electrically insulating filling 9 which at least partially fills the cavity 7 and extends up to the interface surface 8 and thereby forms an interface with at least one of the at least one electrically insulating layer structure 4. The electrically insulating filling 9 and the at least one electrically insulating layer structure 4 can be made of different materials. Alternatively, the electrically insulating filling 9 and the at least one electrically insulating layer structure 4 can be made of the same materials.

The cavity 7 is narrowed toward the first component 5. An area defined on a bottom of the cavity 7 is greater than the area defined by the second component 6 of a percentage range from 1 to 20%.

The cavity 7 extends up to a next conductive layer structure which is, in the embodiment of FIG. 1, an uppermost layer. A height of the cavity 7 along a stack thickness is greater that a height of the second component 6 mounted in the cavity 7.

The stack 2 comprises two vias having two sub-portions 3a, 3b opposed with respect to a stack thickness, each sub-portion 3a, 3b is narrowed toward an internal portion of the stack 2 and both sub-portions 3a, 3b are connected to each other by a narrowed section.

FIG. 2 and FIG. 3 illustrate a method of manufacturing the component carrier 1 according to the embodiment of FIG. 1. In a step S1, a center core is provided by an electrically insulating layer structure 4. The core comprises electrically conductive layer structures 3, for example in the shape of vias. A main cavity 20 is provided in the core, i.e., in the electrically insulating layer structure 4.

In a step S2, a temporary carrier 30 is attached to a bottom main surface of the core, i.e., to a bottom main surface of the electrically insulating layer structure 4.

In a step S3, a first component 5 is placed in the main cavity 20 and attached or adhered to the temporary carrier 30. This is also called as center core technology. The first component 5 has the first pads or contacts 51 which are face down. The first component 5 comprises a stop layer 15, in particular a copper layer, on an upper main surface 14, i.e., at the main surface opposite to the first contacts 51. The stop layer 15 is configured to stop a cavity formation process, which is described later. The stop layer 15 can also be a releasable layer on the upper main surface 14 of the first component 5.

In a step S4, the main cavity 20 is filled or encapsulated by an electrically insulating filling material 40. The electrically insulating filling material 40 can be the same or different from the material of the electrically insulating layer structure 4 which forms the core. The electrically insulating layer structure 40 belongs in its entirety to the at least one electrically insulating layer structure 4.

In a step S5, after curing the electrically insulating filling material 40, the temporary carrier 30 is removed.

In a step S6, at least one build-up layer 50 is provided at a bottom of the intermediate product, where the temporary carrier 30 was previously attached. The build-up layer 50 can be provided by lamination.

In a step S7, a cavity 7 is formed in the electrically insulating filling material 40 (which belongs to the at least one electrically insulating layer structure 4) above the first component 5. The cavity 7 can be formed by etching or by a laser processing. The cavity 7 is delimited by and forms the interface surface 8 of the stack 2. The interface surface 8 forms an interface, which is described later. The first component 5 comprises the stop layer 15, in particular the copper layer, on the upper main surface 14. The stop layer 15 is configured to stop a cavity formation process. That means the stop layer 15 protects the first component 5. An entire bottom of the cavity 7 is therefore defined by the upper main surface 14 of the first component 5.

In a step S8, a second component 6 is mounted to the first component 5 and in the cavity 7. For example, an adhesive 16, in particular an electrically conductive adhesive or a bonding structure can be provided between the first component 5 and the second component 6 to attach the second component 6 to the first component 5. Alternatively, there is no explicit connection structure or direct electrical connection between the first and second components 5, 6. The second component 6 has the first pads or contacts 61 which are face up. The first contacts 61 of the second component 6 are faced in a direction opposite to the first contacts 51 of the first component 5. The second component 6 is aligned to the first component 5. Preferably, the same alignment marks for embedding the first component 5 and for mounting the second component 6 are used.

In a step S9, the cavity 7 is filled by an electrically insulating filling 9 which extends up to the interface surface 8 and thereby forms the above-mentioned interface of the at least one electrically insulating layer structure 4. The electrically insulating filling 9 and the electrically insulating layer structures 40, 4 can be made of the same or different materials. The electrically insulating filling 9 and the electrically insulating layer structure 40 belong in their entirety to the electrically insulating layer structure 4.

Curing the electrically insulating filling 9 involves less shrinkage compared with the prior art because there is no entire through hole through the core 4. The second component 6 is not shifted because it is already attached to the back side of the first component 5.

In a step S10, further built-up layers such as electrically conductive layers 71, 81 or further electrically insulating layers can be provided at both main surfaces. The electrically conductive layers 71, 81 can be patterned in conventional ways. Eventually, the first and second components 5, 6 are encapsulated within four layers 4, 9, 40, 50 which enables a minimized stack up height. It is possible to solder additional components on top of the component carrier 1 for three-dimensional stacking, or simply to cover with a solder resist.

FIG. 4 illustrates a method of manufacturing a component carrier 1 according to an embodiment. The method steps S71 to S73 can be performed after method step S7 of FIG. 3, i.e., after having formed the recess 7. However, contrary to the embodiment of FIG. 3, the first component 5 comprises, in addition to the first contacts 51 being face-down, second contacts 52 being face-up at an opposite main surface. The second contacts 52 of the first component 5 are exposed in the cavity 7.

In a step S71, the second component 6 is placed into the cavity 7 on top of the first component 5. Contrary to the embodiment of FIG. 3, the second component 6 comprises, in addition to the first contacts 61 being face-up, second contacts 62 being face-down at an opposite main surface. The second contacts 62 of the second component 6 are aligned to the second contacts 52 of the first component. The second contacts 62 of the second component 6 can be bonded or soldered to the second contacts 52 of the first component 5. For example, the second contacts 52 of the first component 5 can be connected to second contacts 62 of the second component 6 by a solder layer instead of the adhesive 16 of the embodiment in FIG. 1, FIG. 2, and FIG. 3, or by an electrically conductive adhesive, a sinter structure or a bonding structure such as a hybrid bonding structure, a metal-to-metal bonding structure such as copper to copper, a fusion bonding structure, or a wire bonding structure. The second contacts 62 of the second component 6 are directly contacted to the second contacts 52 of the first component so that wire bonding is avoided and a signal improvement and reliability is achieved.

In a step S72, the cavity 7 is filled by an electrically insulating filling 9 which extends up to the interface surface 8 and thereby forms the above-mentioned interface of the at least one electrically insulating layer structure 4 similar to step S9 in FIG. 3.

In a step S73, further built-up layers such as electrically conductive layers 71, 81 and further electrically insulating layers can be provided at both main surfaces similar to step S10 in FIG. 3. The electrically conductive layers 71, 81 can be patterned in conventional ways.

FIG. 5 illustrates a method of manufacturing a component carrier 1 according to an embodiment. The steps S81 to S83 are similar to steps S71 to S73 in FIG. 4 with the following exception.

In step S81, after having placed the second component 6 into the cavity 7, an underfilling material 17 such as a sealing or any electrically insulating material is applied to the bottom of the cavity 7. The underfilling material 17 surrounds the second contacts 52 of the first component 5 and the second contacts 62 of the second component 6. Preferably, the underfilling material 17 seals the second contacts 62 of the second component 6 so that there are substantially no voids in a gap between the first component 5 and the second component 6.

In a step S82, the cavity 7 is filled by an electrically insulating filling 9, and in a step S83, further built-up layers are provided.

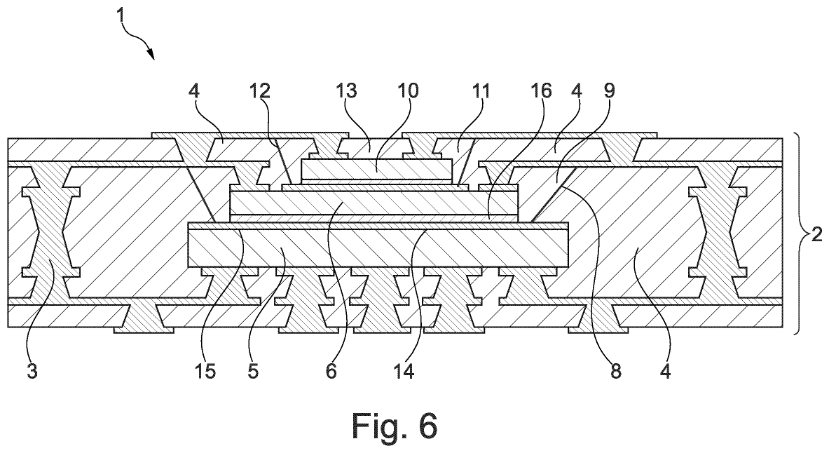

FIG. 6 illustrates a cross-sectional view of a component carrier 1 according to an exemplary embodiment of the invention. The component carrier 1 comprises a stack 2 comprising at least one electrically conductive layer structure 3 and at least one electrically insulating layer structure 4, a first component 5 embedded in the stack 2, a second component 6 mounted on the first component 5 and in a cavity 7 which is delimited by an interface surface 8 of the stack 2, and an electrically insulating filling 9 which at least partially fills the cavity 7 and extends up to the interface surface 8 and thereby forms an interface with at least one of the at least one electrically insulating layer structure 4.

The component carrier 1 further comprises a third component 10 mounted on the second component 6 and in a further cavity 11 which is delimited by a further interface surface 12 of the stack 2, and a further electrically insulating filling 13 which at least partially fills the further cavity 11 and extends up to the further interface surface 12 and thereby forms an interface with at least one of the at least one electrically insulating layer structure 4.

The cavity 7 extends along a direction from the second component 6 to the third component 10 with a width defined on the bottom of the cavity 7 that is greater than the width of the respective second and third components 6, 10 of a percentage range from 1 to 20%. An area defined by a bottom of the further cavity 11 is greater than an area defined by the third component 10 of a percentage range from 1 to 20%.

The first, second, and third component 5, 6, 10 comprise the connecting pads 51, 61, 101 on a respective main surface facing an external surface of the stack, wherein the first, second, and third component 5, 6, 10 comprise a lateral surface, and the electrically insulating layer structure 4 is in contact with the lateral surface and the pads 51, 61, 101 of the first, second and third components 5, 6, 10. The electrically insulating filling material 40 is in contact with the lateral surface and the pad 51 of the first component 5. The electrically insulating filling 9 and the further electrically insulating filling 13 are in contact with the lateral surfaces and the pads 61, 101 of the respective second and third components 6, 10.

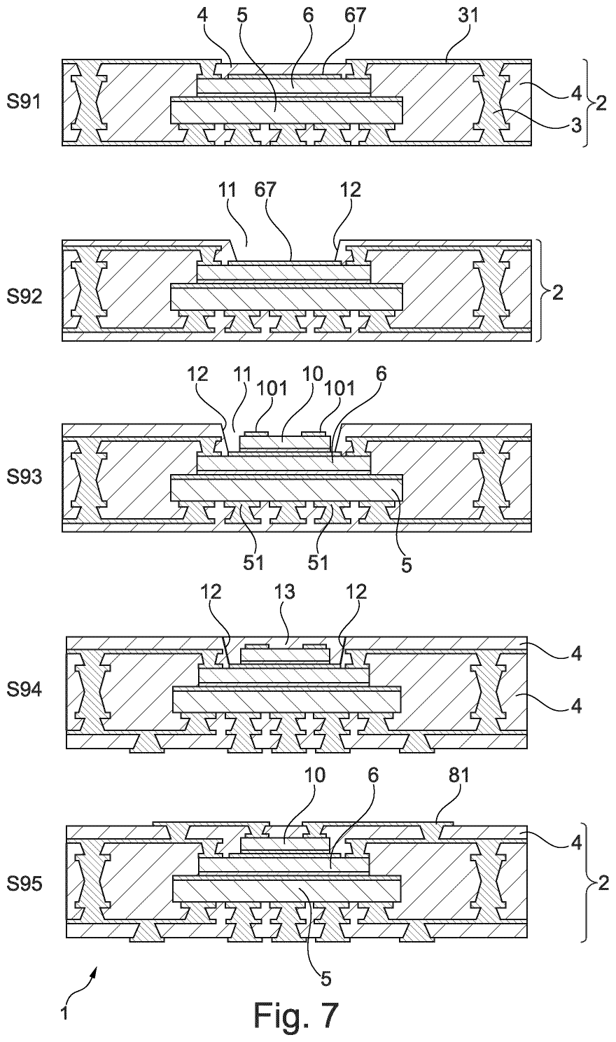

FIG. 7 illustrates a method of manufacturing the component carrier 1 according to the exemplary embodiment of FIG. 6.

Step S91 can follow step S9 in FIG. 3. In the step S91, an electrically conductive layer structure 31 can be applied to an upper surface of the intermediate product which is obtained after step S9 in FIG. 3.

In a step S92, a further cavity 11 is formed in the electrically insulating layer structure 4 above the second component 6. The further cavity 11 can be formed by etching or by a laser processing. The further cavity 11 is delimited by a further interface surface 12 of the stack 2. The further interface surface 12 forms an interface, which is described later. The second component 6 can comprise a stop layer 67, in particular the copper layer, on an upper main surface of the second component 6. The stop layer 67 is configured to stop a cavity formation process. That means the stop layer 67 protects the second component 6. An entire bottom of the further cavity 11 can be defined by the upper main surface of the second component 6.

In a step S93, a third component 10 is mounted on the second component 6 and in the further cavity 11. For example, an adhesive, in particular an electrically conductive adhesive, a bonding structure as described above or a solder structure or a sinter structure can be provided between the second component 6 and the third component 10 to attach the third component 10 to the second component 6. The third component 10 has first pads or contacts 101 which are face up. The first contacts 101 of the third component 101 are faced in a direction opposite to the first contacts 51 of the first component 5. The third component 10 is aligned to the first and/or second component 5, 6. Preferably, the same alignment marks for embedding the third component 10 and for mounting the third component 10 are used.

In a step S94, the further cavity 11 is filled by a further electrically insulating filling 13 which extends up to the further interface surface 12 and thereby forms the above-mentioned interface of the at least one electrically insulating layer structure 4. The further electrically insulating filling 13 and the surrounding electrically insulating layer structure 4 can be made of the same or different materials. The further electrically insulating filling 13 and the surrounding electrically insulating layer structure 4 belong in their entirety to the electrically insulating layer structure 4.

In a step S95, further built-up layers such as an electrically conductive layer 81 or further electrically insulating layers be provided at one or both main surfaces. The electrically conductive layer 81 can be patterned in conventional ways. It is possible to solder additional components on top of the unit for three-dimensional stacking, or simply to cover with a solder resist.

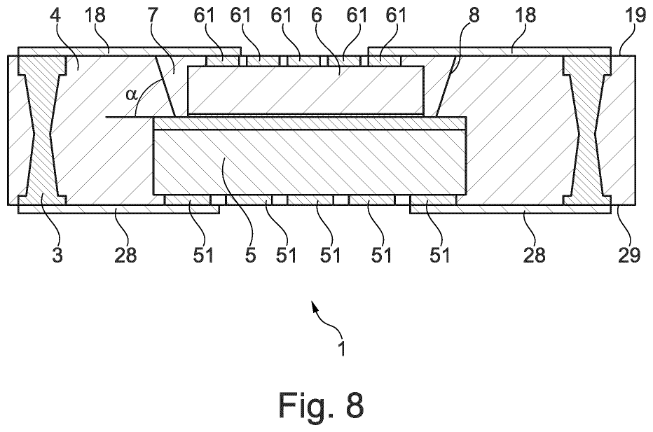

FIG. 8 illustrates a cross-sectional view of a component carrier 1 according to an exemplary embodiment of the disclosure. Pads 51, 61 of the first component 5 and the second component 6 are directly exposed at external main surfaces 19, 29 of the stack 2. The pads 51, 61 of the first and second components 5, 6 and the main surfaces 19, 29 of the stack 2 can be ground. The pads 51, 61 of the first component 5 and the second component 6 are connected to sputtered layers 18, 28 on the external main surfaces 18, 19 of the stack 2. This feature, in conjunction with the features of the cavity 7 and interface surface 8 enhances a reliable and easy positioning of the first and second components 5, 6 even having a compact component carrier 1.

The electric connection on the top side of the components 5, 6, on the same level between the components 5, 6, and stack 2 is realized with a sputtered electrically conductive structure 18, 28 (instead of copper filled laser vias as in FIG. 1). In other words, one or more pads 51, 61 of the components 5, 6 are electrically contacted by the sputtered electrically conductive structures 18, 28 to thereby connect the components 5, 6 directly with electrically conductive layer structures, such as the electrically conductive layers 71, 81 in FIG. 3, FIG. 4, and FIG. 7. For creating the sputtered electrically conductive structures 18, 28, the pads 51, 61 may be exposed on the top side by grinding. Thereafter, metallic material may be applied by sputtering to form the sputtered electrically conductive structures 18, 28. Alternatively, the metallic material can be applied by electroless plating. Thereafter, a lithography and electroplating processes may be executed to obtain a patterned sputtered electrically conductive structure. The direct electric connection to the components 5, 6 can shorten the signal path and reduce a layer count.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A component carrier, comprising:
a stack comprising at least one electrically conductive layer structure and at least one electrically insulating layer structure;
a first component embedded in the stack;
a second component mounted on the first component and in a cavity which is delimited by an interface surface of the stack; and
an electrically insulating filling which at least partially fills the cavity and extends up to the interface surface and thereby forms an interface with at least one of the at least one electrically insulating layer structure.

2. The component carrier according to claim 1, further comprising:
a third component mounted on the second component and in a further cavity which is delimited by a further interface surface of the stack, and
a further electrically insulating filling which at least partially fills the further cavity and extends up to the further interface surface and thereby forms an interface with at least one of the at least one electrically insulating layer structure,
wherein for example an area defined by a bottom of the further cavity is greater than an area defined by the third component of a percentage range from 1 to 20%.

3. The component carrier according to claim 1, further comprising:
a third component mounted side-by-side with the second component on the first component, wherein for example the cavity extends along a direction from the second component to the third component with a width defined on the bottom of the cavity that is greater than the width of the respective second and third components of a percentage range from 1 to 20%.

4. The component carrier according to claim 1,
wherein an entire bottom of the cavity is defined by an upper main surface of the first component.

5. The component carrier according to claim 1, further comprising:
a stop layer on an upper main surface of the first component and configured for stopping a cavity formation process.

6. The component carrier according to claim 1,
wherein the electrically insulating filling and the at least one electrically insulating layer structure are made of the same materials.

7. The component carrier according to claim 1, further comprising at least one of the following:
an electrically conductive adhesive between the first component and the second component;
a non-conductive adhesive between the first component and the second component;
an insulating adhesive between the first component and the second component.

8. The component carrier according to claim 1,
wherein the first component and the second component are electrically coupled with each other directly via their mutually facing main surfaces by a metallic structure,
wherein at least one of the first component and the second component comprises at least one through via passing through the at least one of the first component and the second component,
wherein the metallic structure is bonding structure, a solder structure or a sinter structure.

9.-10. (canceled)

11. The component carrier according to claim 1,
wherein the first component and the second component are electrically coupled with each other indirectly via at least one of the at least one electrically conductive layer structure.

12. The component carrier according to claim 1,
wherein at least one of the at least one electrically insulating layer structure is thermally conductive and comprises a thermal prepreg.

13. The component carrier according to claim 1,
wherein at least one of the first component and the second component is an electronic component.

14. The component carrier according to claim 1,
wherein at least one of the first component and the second component is a thermally conductive block.

15. The component carrier according to claim 1,
wherein a center to center distance of between adjacent pads) of the second component is smaller than a respective center to center distance between adjacent pads of the first component.

16. The component carrier according to claim 1,
wherein the first component has a larger main surface than the second component.

17. The component carrier according to claim 1, comprising at least one of the following features:
wherein the cavity is narrowed toward the first component, wherein an area defined on a bottom of the cavity is greater than the area defined by the second component of a percentage range from 1 to 20%;
wherein the cavity extends up to a next layer structure next to a component area where the cavity merges, wherein the cavity extends up to a next conductive layer structure;
wherein a height of the cavity along a stack thickness is greater than a height of the second component mounted in the cavity;
wherein pads of the first component, the second component, or the third component are directly exposed at an external main surface of the stack, wherein the pads of the first component, the second component, or the third component are connected to a sputtered layer on the external main surface of the stack;
wherein the first, second, and/or third component comprises at least one connecting pad on a respective main surface facing an external surface of the stack, wherein the first, second, and/or third component comprises a lateral surface and the electrically insulating layer structure is in contact with the lateral surface and the at least one pad of the first, second and/or third component, wherein the electrically insulating filling material is in contact with the lateral surface and the pad of the first component and/or wherein the electrically insulating filling and/or the further electrically insulating filling is in contact with the lateral surface and the pad of the respective second and/or third component;
wherein the stack comprises at least one via having two sub-portions opposed with respect to a stack thickness, each sub-portion being narrowed toward an internal portion of the stack and both sub-portions are connected to each other by a narrowed section.

18.-29. (canceled)

30. A method of manufacturing a component carrier, the method comprising:
providing a stack comprising at least one electrically conductive layer structure and at least one electrically insulating layer structure;
embedding a first component in the stack;
mounting a second component on the first component and in a cavity which is delimited by an interface surface of the stack; and
at least partially filling the cavity with an electrically insulating filling which extends up to the interface surface and thereby forms an interface with at least one of the at least one electrically insulating layer structure.

31. The method according to claim 30, further comprising:
using alignment marks for embedding the first component and for mounting the second component.

32. The method according to claim 30,
wherein pads of the first component, the second component, or the third component are directly exposed at an external main surface of the stack; and
the pads of the first component, the second component, or the third component are connected to a sputtered layer on the external main surface of the stack.

33. The method according to claim 32,
wherein a top side of the stack and the pads of the first component, the second component or the third component are ground;
thereafter, the electrically conductive structures are sputtered on a ground surface of the stack and the pads of the first component, the second component or the third component;
thereafter, the sputtered electrically conductive structures are patterned.

34. The method according to claim 30,
wherein the cavity is formed by use of a stop layer or a releasable layer on an upper main surface of the first component, wherein the stop layer is configured for enhancing a cavity formation process.
